(19) United States
(12) Patent Application Publication
(10) Pub. No.: US 2018/0111853 A1
(43) Pub. Date: Apr. 26, 2018

(54) WATER TREATMENT APPARATUS FOR THE STERILIZATION OF WATER USING ELECTRICAL ENERGY

(71) Applicant: Hyo Sung TAK, Busan (KR)

(72) Inventor: Hyo Sung TAK, Busan (KR)

(21) Appl. No.: 15/361,217

(22) Filed: Nov. 25, 2016

(30) Foreign Application Priority Data
Oct. 25, 2016 (KR) 10-2016-0139191

(51) Int. Cl. C02F 1/46

(52) U.S. Cl. CPC C02F 1/4608; H01L 29/7393; C02F 2307/10; C02F 2303/04

(57) ABSTRACT

A water treatment apparatus includes sterilization means capable of effectively suppressing the proliferation of bacteria in a water storage tank of a humidifier or a water purifier by using only electrical energy without the need for any chemical sterilization process. Specifically, the water treatment apparatus includes a water storage tank, electrode rods made of a metal selected from Pt, Au, Ag, Cu, Sn, and alloys thereof and arranged to face each other at both sides on the bottom surface of the water storage tank, and a field effect transistor connected to the electrode rods through 2.0 to 5.0 mm thick electric wires. The electrode rods at one side are connected to a positive (+) electrode and the electrode rods at the other side are connected to a negative (−) electrode.

### BACKGROUND OF THE INVENTION

### 1. Field of the Invention

The present invention relates to a water treatment-related technology for the sterilization of water, and more specifically to a water treatment apparatus including sterilization means capable of effectively suppressing the proliferation of bacteria in a water storage tank of a humidifier or a water purifier by using only electrical energy without the need for any chemical sterilization process.

### 2. Description of the Related Art

Generally, humidifiers are devices that artificially produce and spray water vapor to increase the humidity level of indoor air. Humidifiers are divided into heater humidifiers and ultrasonic humidifiers depending on how they produce water vapor. Heater humidifiers are operated in such a manner that water stored in a water chamber is heated to a predetermined temperature and the resulting water vapor is naturally sprayed indoors. Ultrasonic humidifiers are operated in such a manner that ultrasonic waves are generated in water stored in a water chamber by vibration to micronize the water particles and the micronized water particles are sprayed indoors.

When water is stored in such humidifiers for a long time, bacteria tend to proliferate and contaminate the water. The contaminated water is extremely harmful to humans, particularly patients and infants, when sprayed indoors without being sterilized. In some humidifiers, sterilizing chemicals are mixed with water in a water tank to avoid water contamination. However, the use of toxic chemicals, such as polyhexamethylene guanidine (PHMG), for water sterilization causes infant asphyxia, which is issued as a serious social problem.

Water purifiers are generally divided into direct receiving and storage types according to the presence or absence of purified water tanks. A direct receiving type water purifier is operated by the pressure of raw water and includes various filters, including a sediment filter through which particulate residues are removed from raw water, an activated carbon filter through which chlorines and odors are removed, an antibacterial filter, a ceramic filter, and other filters.

Although special care is taken to seal purified water storage tanks, bacteria entering from ambient air and bacteria inhabiting filters increase the possibility of contamination of water in the purified water storage tanks. Particularly, since the use of functional filters for water purification leads to the removal of most residual chlorines, no practical technology has been established that protects water from general bacterial and biological contamination.

Increasing operation of heating systems in the winter in Korea makes indoor air dry to cause respiratory diseases in the elderly and infirm, which is responsible for the frequent use of humidifiers for humidity control.

Humidifiers are largely divided into heater humidifiers and ultrasonic humidifiers depending on their heating types.

Heater humidifiers are operated in such a manner that water in an atomization tank is heated to a high temperature to produce water vapor and the water vapor is naturally sprayed indoors. Ultrasonic humidifiers are operated in such a manner that water in an atomization tank is micronized by an ultrasonic transducer and the micronized water particles are sprayed indoors.

Heater humidifiers require high capacity heaters for water heating/evaporation and are disadvantageous in that a sufficient amount of atomized particles is not produced.

In an ultrasonic humidifier, water particles are atomized by an ultrasonic transducer and are ejected by a blower. However, when contaminated blown air comes into contact with the water in contact with the ultrasonic transducer and the atomized particles, bacteria tend to proliferate. When the atomized particles are sprayed, the bacteria are scattered in air, causing serious damage to the health of the elderly and infirm.

Many methods have been proposed to suppress the proliferation of bacteria in atomization tanks in contact with ultrasonic transducers, for example, by purifying water in water tanks or sterilizing water in water tanks before contact with ultrasonic transducers.

Specifically, Korean Patent No. 164173 proposes a humidifier including a heating chamber in which water is sterilized by heating before it reaches an ultrasonic transducer from a water tank. Further, Korean Patent Publication No. 2001-88754 proposes a humidifier including an evaporator mounted in a tube through which atomized particles are released. The evaporator is designed as a heat radiating plate including a heater embedded therein. Further, Korean Patent Publication No. 1998-56268 proposes a humidifier structure in which a hot air furnace including a heater coil arranged at an outlet thereof and a fan positioned at the rear thereof is employed such that hot air is scattered on the water surface above an ultrasonic transducer to increase the temperature of atomized particles and assist in the atomization function of an ultrasonic transducer. However, these humidifiers generally use tap water that does not need to be sterilized. It is thus inefficient to separately boil or purify water in atomization tanks.

According to the experimental data reported in the Eight O'Clock News of SBS, a Korean broadcasting network, on Dec. 25, 2002, the number of bacteria in water supplied to an ultrasonic humidifier is limited to 10 counts/ml on the first day by residual chlorines, and thereafter, it increases to 600 counts/ml and 1×10⁵ counts/ml on days 2 and 3, respectively.

In a general humidifier, bacteria exist on the bottom, for example, in dust accumulated on the bottom, are incorporated into an atomization tank when air enters, proliferate under the humidity and temperature conditions of the atomization tank, are scattered, together with atomized particles, in indoor air, and spread indoors. Accordingly, if the humidifier is used improperly, indoor bacterial contamination spreads, resulting in severe damage to health rather than being helpful in health.

The proliferation of bacteria in an atomization tank of a humidifier is caused by contaminated indoor air supplied from a blower and increases exponentially under proper humidity conditions. This bacterial proliferation is not solved by the supply of purified water and cannot be prevented by partial heating of water supplied from a water tank to the atomization tank so long as water in the atomization tank is not maintained above a sterilization temperature for a sufficient time for sterilization.

In connection with prior art water purifiers, Korean Patent No. 10-1510628 discloses a sterilization system for a water purifier in which sterilized water is smoothly mixed with water in a storage tank. The sterilization system includes a water storage tank having a guide channel for guiding the flow of water, a sterilization unit connected to the guide channel to sterilize water discharged from the storage tank, and a drive unit for circulating the water sterilized by the sterilization unit and returning the circulating water to the storage tank. The storage tank has a plurality of communication holes through which the internal space of the storage tank is in communication with the guide channel. The guide channel has at least one outflow channel through which the flow of the stored water is guided from the storage tank to the sterilization unit and at least one inflow channel through which the flow of the sterilized water is guided from the sterilization unit to the storage tank. The sterilization system uses an ultraviolet lamp for sterilizing inflow water, a silver ion generator, an electrolytic sterilizer, and one or more filters selected from ultrafiltration filters (UFs), silver-added activated carbon filters, and antibacterial ceramic filters.

### SUMMARY OF THE INVENTION

The present invention is intended to provide novel sterilization means that can effectively suppress the proliferation of bacteria in a water storage tank of a humidifier or water purifier structure in an easy and safe manner.

An object of the present invention is to provide water treatment means of a water treatment system, such as a humidifier or a water purifier, that can kill microbial bacteria by a physical process for instantaneous sterilization including applying electrical energy to water in a water storage tank.

The present inventor has conducted research to develop a technology that can be applied to a water treatment apparatus, such as a humidifier or water purifier structure, for supplying sterilized water from a water storage tank. As a result, the present inventor has found that electric power is applied to electrode rods made of a metal selected from Pt, Au, Ag, Cu, Sn, and alloys thereof and arranged to face each other at both sides on the bottom surface of a water storage tank of a water treatment apparatus, the electrode rods at one side being connected to a positive (+) electrode, the electrode rods at the other side being connected to a negative (−) electrode, the electrode rods at both sides being connected to a field effect transistor through 2.0 to 5.0 mm thick electric wires, water in the water storage tank can be instantaneously sterilized by electrical energy to kill microbial bacteria and the sterilized water can be supplied. The present invention has been accomplished based on this finding.

The field effect transistor used in the water treatment apparatus of the present invention may be selected from IGBT and MOSFET systems. The water treatment apparatus of the present invention is applicable to a humidifier or a water purifier. In this case, a detection sensor may be mounted in a connection unit of the apparatus or on the surface of the apparatus. When the connection unit is disconnected or an animal or human approaches the surface of the apparatus, a control unit interrupts the internal power of the water treatment apparatus, ensuring safety of the apparatus.

The water treatment apparatus may be applied to a humidifier. In this case, a mist vent port consisting of a plurality of 5-15 cm high connection pipes is formed such that mist is released at a height of 25 to 75 cm.

Thus, the present invention also provides a method of using a water treatment apparatus for sterilizing water in a water storage tank and supplying the sterilized water, the method including: constructing a water treatment apparatus in which electrode rods made of a metal selected from Pt, Au, Ag, Cu, Sn, and alloys thereof are arranged to face each other at both sides on the bottom surface of a water storage tank, the electrode rods at one side are connected to a positive (+) electrode, the electrode rods at the other side are connected to a negative (−) electrode, and the electrode rods are connected to a field effect transistor through 2.0 to 5.0 mm thick electric wires (step 1); applying electric power to the electrode rods such that water in the water storage tank is instantaneously sterilized by electrical energy to obtain sterilized water (step 2); and supplying the sterilized water (step 3).

Step 3 may be applied to a humidifier. In this case, the sterilized water is discharged to the outside through a mist vent port by a high frequency vibrator. Alternatively, step 3 may be applied to a water purifier. In this case, the sterilized water is supplied as feed water for animals or drinking water for humans.

The field effect transistor (FET) is a device used when a large output is required from a small input. General transistors are used for current amplification whereas field effect transistors (FETs) are devices for voltage amplification. Field effect transistors are also called “transistors with vacuum tube characteristics” due to their high input impedance. The field effect transistor used in the present invention is preferably selected from IGBT and MOSFET systems.

The water treatment apparatus of the present invention is preferably used for water sterilization. Specifically, electrode rods A and B are arranged on the bottom surface of a water storage tank. The number of the electrode rods is typically 2. Four electrode rods may be arranged when the bottom area is large. The electrode rods protrude slightly from the bottom surface of the water storage tank. When a positive (+) electrode is connected to the electrode rod A and a negative (−) electrode is connected to the electrode rod B, an electric current flows instantaneously, and as a result, water in the water storage tank is sterilized by electrical energy. The operation of the water treatment apparatus is stopped by power interruption when the amount of the electric current flowing between the electrode rods A and B is not detected, abnormal operation of the apparatus is detected by a sensor mounted inside or outside the apparatus or the flow of the electric current is above a predetermined value.

The method of the present invention may further include informing a user of the shortage of water in the water storage tank or the connection or disconnection between the field effect transistor and the electrode rods after stopping of the apparatus. It should be understood that the method can further include any technique applicable to conventional water treatment apparatuses, for example, the step of informing of a user of the cleaning state of the water storage tank.

The water treatment apparatus of the present invention is effective in inhibiting the proliferation of bacteria in water stored in a water storage tank of a conventional humidifier or water purifier structure by sterilization in an easy and safe manner.

In addition, the water treatment apparatus of the present invention can kill microbial bacteria by a physical process for instantaneous sterilization including applying electrical energy to water in a water storage tank.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a perspective view illustrating the appearance of a humidifier according to one embodiment of the present invention;

FIG. 2 is an exploded perspective view of the humidifier of FIG. 1;

FIGS. 3A and 3B illustrate plan and side views of a water storage tank of the humidifier of FIG. 1;

FIG. 4 is a modification of the humidifier of FIG. 1;

FIG. 5 is a side view of a water purifier to which a water treatment apparatus according to one embodiment of the present invention is applied; and

FIG. 6 is an analytical report of water obtained from a water purifier to which a water treatment apparatus of the present invention is applied.

### DETAILED DESCRIPTION OF THE INVENTION

Preferred embodiments of the present invention will now be described in detail with reference to the accompanying drawings in which a humidifier and a water purifier including a water treatment apparatus are illustrated.

However, the embodiments of the present invention are provided for illustrative purposes only and may be modified in different forms by adding technical features of the present invention to water storage tanks of conventional humidifier or water purifier structures. It is to be understood that similar modifications, equivalents, and substitutes that do not depart from the spirit and scope of the present invention are encompassed in the present invention.

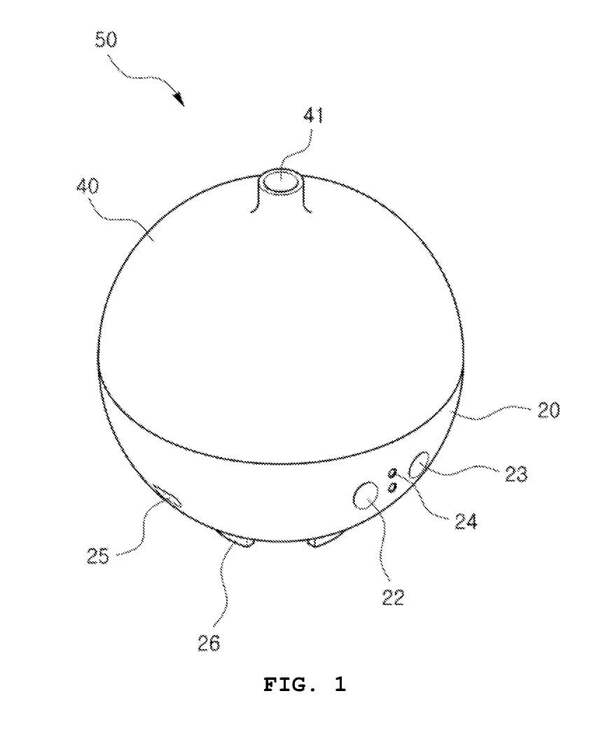

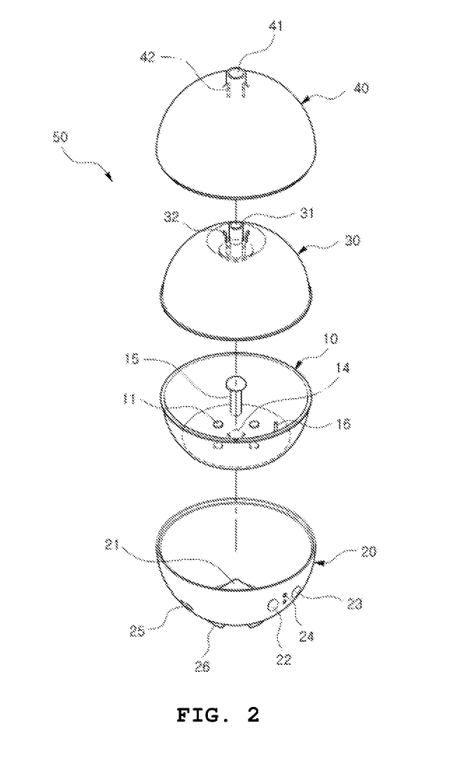

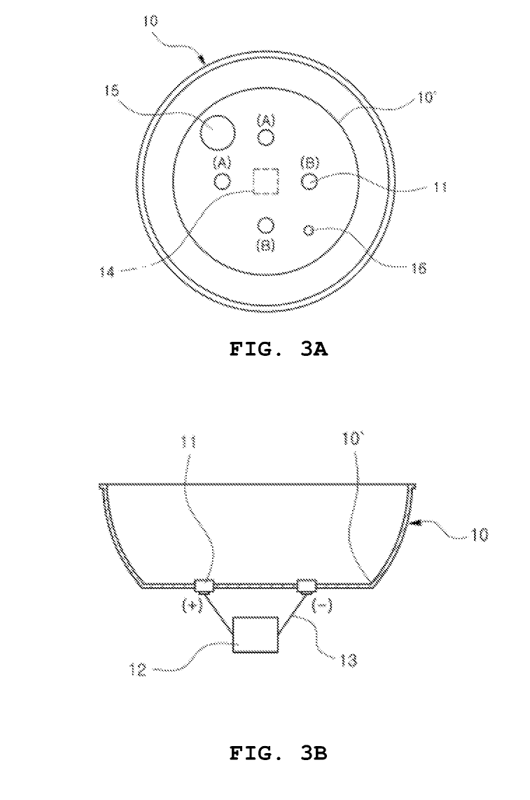

FIG. 1 is a perspective view illustrating the appearance of a humidifier according to one embodiment of the present invention and explains how the present invention is applied to a conventional humidifier. FIG. 2 is an exploded perspective view illustrating the internal structure of the humidifier of FIG. 1. FIG. 3 illustrates plan and side views of a water storage tank of the humidifier of FIG. 1 and explains how technical features of the present invention are applied to the water storage tank.

The humidifier 50 illustrated in FIG. 1 includes an upper outer barrel body 40 and a lower outer barrel body 20 coupled to each other. A lighting control button 22 and a humidifier control button 23 are provided on the lower outer barrel body 20 and are push-operated. The operation states are displayed through LED display lamps 24. A connection unit 25 is mounted on the lower outer barrel body 20. A DC plug power source is inserted into the connection unit 25. The upper outer barrel body 40 has a mist vent port 41. Although not illustrated in FIG. 1, a semicircular upper inner barrel body 30 is in close contact with the inner surface of the upper outer barrel body 40, which is also semicircular. A water storage tank 10 in the shape of a flat-bottom bowl is in close contact with the upper surface of a control panel 21 positioned inside the lower outer barrel body 20. The humidifier 50 can be provided in the form of a ball as a whole.

FIG. 2 is an exploded perspective view illustrating the internal structure of the humidifier of FIG. 1. The lower outer barrel body 20 has a foot 26. The lighting control button 22, the humidifier control button 23, the LED display lamps, and the connection unit 25 are provided on the lower outer barrel body 20. The water storage tank 10 is mounted on the control panel 21 positioned in a recess formed in the lower outer barrel body 20. The water storage tank 10 has a flat bottom structure. If a bent portion is formed between the bottom and the extending wall surface of the water storage tank 10, there is a risk that sediments or residues may be caught in the bent portion. Thus, it is preferred that the portion between the bottom and the extending wall surface of the water storage tank 10 is as rounded as possible without being bent. An ultrasonic spray hole 14 is formed at the center of the bottom of the water storage tank 10. Ultrasonic vibration is caused through the ultrasonic spray hole 14. An air intake port 15 is formed on one side of the bottom of the water storage tank. Air is blown from a blower fan 16 mounted on the underside of the water storage tank 10. A level detection sensor 17 is mounted on one side of the bottom of the water storage tank. The upper inner barrel body 30 can be provided in the upper outer barrel body 40 due to its semicircular structure. The upper inner barrel body 30 is connected to the central portion of the upper outer barrel body through a central air through-hole 31. An outwardly latching member 32 is formed along the outer circumference of the central air through-hole 31. Although invisible from the outside, a latching portion 42 is formed inside the mist vent port 41. Due to this structure, the outwardly latching member 32 of the upper inner barrel body 30 is fastened to the latching portion 42, and as a result, the upper inner barrel body 30 is in close contact with the inner surface of the upper outer barrel body 40. The bottom of the water storage tank 10 is seated on the control panel 21 of the lower outer barrel body 20. The lower outer barrel body 20 is coupled to the upper outer barrel body 40 in a state in which the upper inner barrel body 30 is fitted into the upper outer barrel body 40.

FIGS. 3A and 3B illustrate some main elements of the water treatment apparatus. As illustrated in FIGS. 3A and 3B, the water treatment apparatus is characterized in that the electrode rods A and B protrude slightly from the bottom surface of the water storage tank 10 and are connected to (+) and (−) electrodes, respectively, and water in the water storage tank is sterilized by electrical energy when an electric current flows instantaneously. The electrode rods are made of a metal selected from Pt, Au, Ag, Cu, Sn, and alloys thereof and are arranged to face each other at both sides of the bottom surface of the water storage tank. The electrode rods A at one side are connected to a positive (+) electrode and the electrode rods B at the other side are connected to a negative (−) electrode. The electrode rods at both sides are connected to a field effect transistor interposed therebetween through 2.0 to 5.0 mm thick electric wires. When electric power is instantaneously applied to the electrode rods, water in the water storage tank is instantaneously sterilized by electrical energy as physical means to instantaneously kill microbial bacteria. This sterilization is based on the ability of the field effect transistor to produce a large output from a small input. Although four electrode rods 11 are illustrated in this figure, it should be understood that the number of the electrode rods may vary depending on the capacity or size of the humidifier. For example, two or six electrode rods may be arranged to face each other.

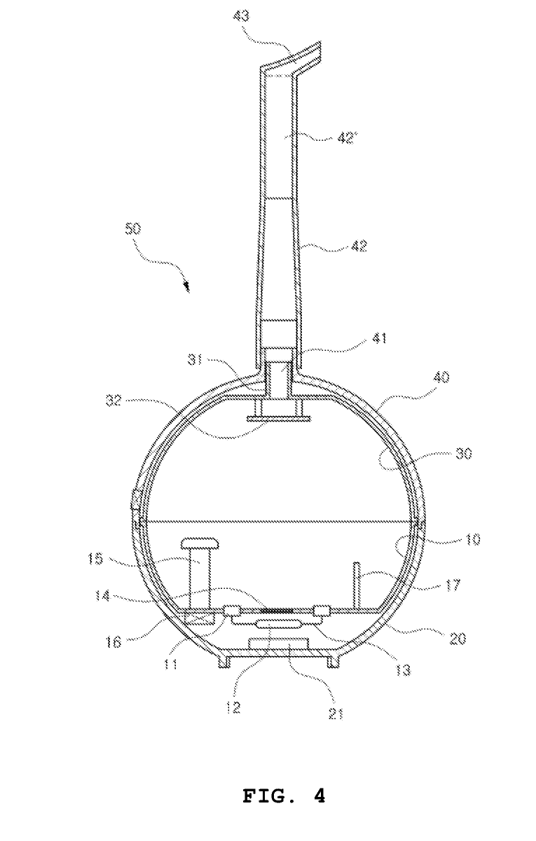

FIG. 4 is a see-through view illustrating a modified internal structure of the humidifier in which a mist vent port is formed at a high position. The humidifier includes a lower outer barrel body 20 and an upper outer barrel body 40 coupled to each other. The lower outer barrel body 20 has a lighting control button 22 and a humidifier control button 23 provided therein. The lighting control button 22 and the humidifier control button 23 are push-operated. The operation states are displayed through LED display lamps 24. A control unit 21 is positioned in the central portion of the lower outer barrel body 20. For example, the control unit 21 controls an ultrasonic spray hole 14 through which ultrasonic vibration is caused. Electrode rods are arranged on the bottom surface of a water storage tank 10 and are connected to (+) and (−) electrodes between which a field effect transistor is interposed. When an electric current flows through 2.0 to 5.0 mm thick electric wires, water in the water storage tank is instantaneously sterilized by electrical energy. A planar blocking plate 32 is provided in an upper inner barrel body 30 seated inside the upper outer barrel body 40 to block mist produced in the humidifier from being directly released. The mist is released through the sides of the blocking plate. A plurality of connectors 42 and 42′ are connected between a vent port 41 and a mist spray rod 43 to allow the release of mist at a position higher than the humidifier.

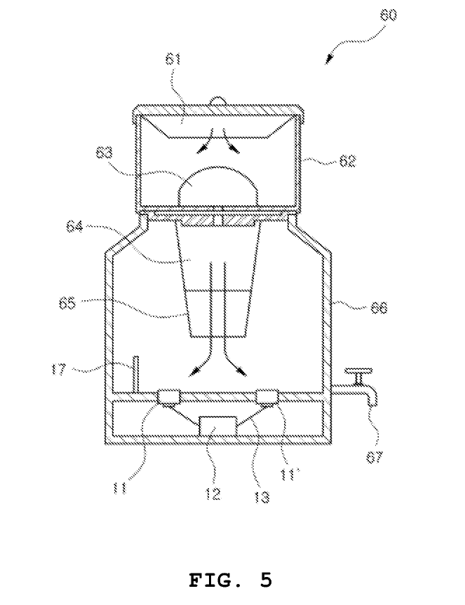

In the humidifier structures explained with reference to FIGS. 1 to 4, the conductive electrode rods are arranged to face each other at both sides on the bottom surface of the water storage tank, the electrode rods at one side are connected to a (+) electrode, the electrode rods at the other side are connected to a (−) electrode, and the electrode rods at both sides are connected to a field effect transistor interposed therebetween through the 2.0 to 5.0 mm thick electric wires. When electric power is applied to the electrode rods, water in the water storage tank is instantaneously sterilized by electrical energy to kill microbial bacteria. The same principle can be applied to a water purifier structure having a water storage tank. FIG. 5 illustrates another embodiment of the water treatment apparatus of the present invention.

FIG. 5 illustrates a water purifier 60 to which a water treatment apparatus according to one embodiment of the present invention is applied. In the water purifier, raw water is passed through a bag filter 61, and as a result, rust and impurities are removed from the raw water. The purified raw water enters an upper water storage tank 62 and is then passed through a pre-carbon filter 63 for the removal of heavy metals and harmful substances. The resulting water is passed through a through-hole in communication with a lower water storage tank 66 and formed on the bottom of the upper water storage tank 62 and is then passed through a filter 64 for the removal of contaminants. Subsequently, gaseous harmful substances dissolved in the water are removed by a post-carbon filter 65. Then, the purified water is stored in a lower water storage tank and is supplied as drinking water through a water supply valve 67. The water treatment apparatus of the present invention is applied to the water purifier 60. Specifically, conductive electrode rods made of a metal selected from Pt, Au, Ag, Cu, Sn, and alloys thereof are arranged to face each other at both sides on the bottom surface of the water storage tank 66, the electrode rods at one side are connected to a (+) electrode, the electrode rods at the other side are connected to a (−) electrode, and the electrode rods at both sides are connected to a field effect transistor interposed therebetween through 2.0 to 5.0 mm thick electric wires. When electric power is instantaneously applied to the electrode rods, water in the water storage tank is instantaneously sterilized by electrical energy as physical means to instantaneously kill microbial bacteria. The sterilized water can be supplied as purified water. This sterilization is based on the ability of the field effect transistor to produce a large output from a small input. When water reaches to a desired level set by a level detection sensor 17 mounted inside the lower water storage tank 66, the electrode rods are connected to (+) and (−) electrodes between which the field effect transistor is interposed and electric power is applied to the electrode rods. As a result, the water stored in the water storage tank is sterilized by electrical energy. The operation of the apparatus is stopped by power interruption when the amount of the electric current flowing between the facing electrode rods is not detected, abnormal operation of the apparatus is detected by a sensor mounted inside or outside the apparatus or the flow of the electric current is above a predetermined value. The water treatment apparatus of the present invention may further include a sensor (not illustrated) for detecting the amount of the electric current flowing between the electrode rods 11. The sensor is connected to the control unit 21. The voltage applied to the electrode rods can be controlled to 230-500 volts by the control unit 21 in response to signals input from the sensor.

The water treatment apparatus is constructed such that when water stored in the water storage tank 10 of the humidifier or the lower storage tank 66 of the water purifier is used up or the body of the apparatus loses its balance to expose the electrode rods 11 from the water, no electric current flows between the electrode rods 11, which is detected by the current detection sensor. Preferably, the control unit receives signals detected by the current detection sensor to stop the operation of the blower fan 16 or the ultrasonic transducer 14, so that the electrical function of the apparatus can be stopped. After the operation of the apparatus is stopped, the shortage of water or the disconnection state of the apparatus is displayed through display means of the LED display lamps or is delivered as voice.

The water treatment apparatus of the present invention is applicable to humidifiers and water purifiers. The water treatment apparatus of the present invention can also be applied to medical sterilizers, such as endoscopes, and storage systems for liquid foods, for example, meat broth for cold noodles and sweet rice drink, where sterilization is needed. Also in this case, electrode rods made of a metal selected from Pt, Au, Ag, Cu, Sn, and alloys thereof are arranged to face each other at both sides on the bottom surface of a storage tank, the electrode rods at one side are connected to a (+) electrode, the electrode rods at the other side are connected to a (−) electrode, and the electrode rods at both sides are connected to a field effect transistor interposed therebetween through 2.0 to 5.0 mm thick electric wires. Due to this construction, when electric power is instantaneously applied to the electrode rods, a content in the storage tank is instantaneously sterilized by using only electrical energy as physical means to instantaneously kill microbial bacteria. This sterilization is based on the ability of the field effect transistor to produce a large output from a small input. The present inventor plans to apply for patents for the related techniques.

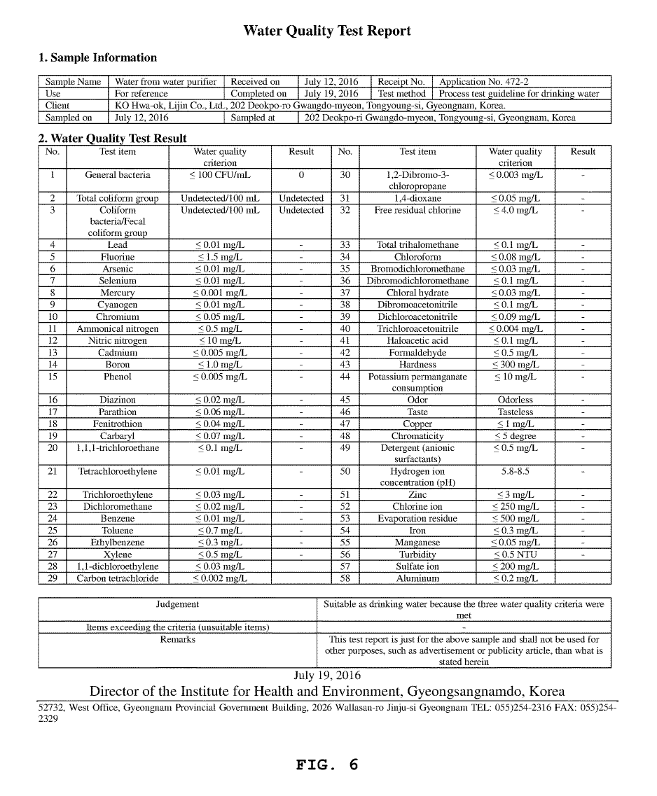

The present inventor requested to the Institute for Health and Environment, Gyeonsangnamdo, Korea, on Jul. 12, 2016 to confirm whether drinking water obtained from the water purifier to which the water treatment apparatus of the present invention is applied meets the test requirements for drinkable water. According to the results received on Jul. 19, 2016, the drinking water met all of the requirements. FIG. 6 shows the analytical report of the water obtained from the water purifier.

As is apparent from the above description, the water treatment apparatus of the present invention instantaneously kills microbial bacteria by simple electrical energy as physical means. Although humidifiers and water purifiers have been mentioned as the exemplary embodiments of the present invention, those skilled in the art will appreciate that various changes or modifications may be made to these embodiments without departing from the spirit and scope of the invention.

What is claimed is:

1. A water treatment apparatus comprising a water storage tank, electrode rods made of a metal selected from Pt, Au, Ag, Cu, Sn, and alloys thereof and arranged to face each other at both sides on the bottom surface of the water storage tank, the electrode rods at one side being connected to a positive (+) electrode and the electrode rods at the other side being connected to a negative (−) electrode, and a field effect transistor connected to the electrode rods through 2.0 to 5.0 mm thick electric wires, wherein when electric power is applied to the electrode rods, water in the water storage tank is instantaneously sterilized by electrical energy to kill microbial bacteria and the obtained sterilized water is supplied.

2. The water treatment apparatus according to claim 1, wherein the field effect transistor is selected from IGBT and MOSFET systems.

3. The water treatment apparatus according to claim 1, further comprising a detection sensor mounted in a connection unit of the water treatment apparatus or on the surface of the water treatment apparatus and a control unit adapted to interrupt the internal power of the water treatment apparatus when the connection unit is disconnected or an animal or human approaches the surface of the apparatus.

4. The water treatment apparatus according to claim 1, wherein when the water treatment apparatus is applied to a humidifier, a mist vent port consisting of a plurality of 5-15 cm high connection pipes is formed such that mist is released at a height of 25 to 75 cm.

5. A method of using a water treatment apparatus, the method comprising: constructing a water treatment apparatus in which electrode rods made of a metal selected from Pt, Au, Ag, Cu, Sn, and alloys thereof are arranged to face each other at both sides on the bottom surface of a water storage tank, the electrode rods at one side are connected to a positive (+) electrode, the electrode rods at the other side are connected to a negative (−) electrode, and the electrode rods at both sides are connected to a field effect transistor through 2.0 to 5.0 mm thick electric wires (step 1); applying electric power to the electrode rods such that water in the water storage tank is instantaneously sterilized by electrical energy to obtain sterilized water (step 2); and supplying the sterilized water (step 3).

6. The method according to claim 5, wherein when step 3 is applied to a humidifier, the sterilized water is discharged to the outside through a mist vent port by a high frequency vibrator.

7. The method according to claim 5, wherein when step 3 is applied to a water purifier, the sterilized water is supplied as feed water for animals or drinking water for humans.
